(19) United States
(12) Patent Application Publication
(10) Pub. No.: US 2024/0369689 A1
(43) Pub. Date: Nov. 7, 2024

(54) Multi-chip transceiver array devices

(71) Applicant: LYTE AI, INC., Mountain View, CA (US)

(72) Inventors: Arman Hajati, San Carlos, CA (US); Yuval Gerson, Sunnyvale, CA (US); Alexander Shpunt, Saratoga, CA (US)

(21) Appl. No.: 18/689,440

(22) PCT Filed: Oct. 24, 2022
(86) PCT No.: PCT/US2022/047516

§ 371 Date: Mar. 6, 2024

Related U.S. Application Data
(60) Provisional application No. 63/272,248, filed on Oct. 27, 2021.

(51) Int. Cl. G01S 7/481; G01S 17/89; G02B 26/12; H01L 23/00; H01L 25/18

(52) U.S. Cl. CPC G01S 7/4816; G01S 7/4817; G01S 17/89; G02B 26/12; H01L 25/18; H01L 24/16; H01L 2224/16145

(57) ABSTRACT

An optoelectronic device (20, 90, 120) includes a photonic integrated circuit (PIC) (24, 92, 94, 126), which includes a PIC substrate (34), having a first side mounted on a carrier substrate (26, 96), first electrical connection pads (70, 130) on a second side of the PIC substrate, optical waveguides (52) on the PIC substrate, and electrical conductors (68, 134) disposed on the PIC substrate and connecting to one or more of the first electrical connection pads. At least one electronic integrated circuit (22, 100, 122, 124) includes a semiconductor substrate (74) having a third side mounted on the second side of the PIC substrate and second electrical connection pads (72, 128) on the semiconductor substrate in electrical communication with the first electrical connection pads. One or more electronic circuit components (76, 78, 80, 82) on the semiconductor substrate are connected electrically to the second electrical connection pads.

### CROSS-REFERENCE TO RELATED APPLICATION

This application claims the benefit of U.S. Provisional Patent Application 63/272,248, filed Oct. 27, 2021, which is incorporated herein by reference.

### FIELD OF THE INVENTION

The present invention relates generally to devices and methods for optical sensing and imaging, and particularly to integrated photonic devices and systems incorporating such devices.

### BACKGROUND

In many optical sensing applications, multiple points on a target are irradiated by an optical beam or beams, and the reflected radiation from each point is processed to analyze properties of the target. In some applications, such as optical coherence tomography (OCT) and continuous-wave (CW) LiDAR, a coherent beam is transmitted toward the target, and the reflected radiation is sensed and processed coherently with the transmitted radiation. To sense the properties of the target with high resolution, the transmitted beam may be scanned over the target area, or an array of multiple beams may be transmitted and sensed simultaneously using an array of receivers.

The terms “optical,” “light.” and “optical radiation,” as used in the present description and in the claims, refer to electromagnetic radiation in any of the visible, infrared, and ultraviolet spectral ranges.

### SUMMARY

Embodiments of the present invention that are described hereinbelow provide improved systems, devices, and methods for optical sensing.

There is therefore provided, in accordance with an embodiment of the invention, an optoelectronic device, including a carrier substrate and a photonic integrated circuit (PIC). The PIC includes a PIC substrate, having a first side mounted on the carrier substrate, first electrical connection pads disposed on a second side of the PIC substrate, opposite the first side, optical waveguides disposed on the PIC substrate, and electrical conductors disposed on the PIC substrate and connecting to one or more of the first electrical connection pads. At least one electronic integrated circuit includes a semiconductor substrate having a third side mounted on the second side of the PIC substrate, second electrical connection pads disposed on the semiconductor substrate in electrical communication with the first electrical connection pads, and one or more electronic circuit components disposed on the semiconductor substrate and connected electrically to the second electrical connection pads.

In some embodiments, the device includes one or more optoelectronic components disposed on the PIC substrate in optical communication with one or more of the optical waveguides and in electrical communication with one or more of the electrical conductors. In some of these embodiments, at least one of the optoelectronic components is configured to exchange electrical signals with at least one of the electronic circuit components via the first and second electrical connection pads. In a disclosed embodiment, the at least one of the optoelectronic components includes an optical transmitter, and the at least one of the electronic circuit components includes a drive circuit, which is coupled via the first and second electrical connection pads to control the optical transmitter.

In some embodiments, the one or more optical components include an array of transceiver cells, and the optical transmitter includes a radiation source configured to generate one or more output beams of optical radiation and an optical network coupled between the radiation source and the transceiver cells, and the drive circuit is configured to control the optical network so as to multiplex the one or more output beams among the transceiver cells.

Additionally or alternatively, the optical transmitter is configured to generate an output beam of coherent radiation, and the one or more optoelectronic components include at least one coherent sensor, which is configured to mix a part of the output beam with incoming optical radiation that is incident on the at least one coherent sensor and to output signals in response to the mixed optical radiation.

Further additionally or alternatively, the at least one of the optoelectronic components includes at least one sensor, which is configured to output signals in response to optical radiation that is incident on the at least one sensor, and the at least one of the electronic circuit components includes one or more signal processing circuits, which are coupled via the first and second electrical connection pads to process the signals output by the at least one sensor. In a disclosed embodiment, the at least one sensor includes an array of optical sensors, and the one or more electronic circuit components include a multiplexing circuit, which is configured to couple the optical sensors selectively to the one or more signal processing circuits.

In some embodiments, the second electrical connection pads are disposed on the third side of the semiconductor substrate in alignment with and bonded to the first electrical connection pads.

Additionally or alternatively, the at least one electronic integrated circuit includes first and second electronic integrated circuits, both mounted on the second side of the PIC substrate, wherein the first electronic integrated circuit is in electrical communication with the second electronic integrated circuit via one of the electrical conductors connecting two of the first electrical connection pads on the PIC substrate.

In a disclosed embodiment, the PIC includes at least one conductive via, coupled between a conductive trace on the carrier substrate and at least one of the first electrical connection pads, which is in electrical communication with at least one of the second electrical connection pads, and at least one of the electronic circuit components is connected through the at least one of the first electrical connection pads, the at least one of the second electrical connection pads, and the at least one conductive via to the conductive trace on the carrier substrate.

There is also provided, in accordance with an embodiment of the invention, an optical scanner, including a body configured to rotate about an axis and a plurality of planar reflective facets disposed on the body at different, respective azimuthal angles about the axis and tilted relative to the axis at different, respective inclination angles.

Some embodiments provide optical apparatus, including such a scanner, an array of optical cells having respective optical apertures, and optics configured to image the optical apertures via the reflective facets of the optical scanner onto respective fields of view on a target, whereby rotation of the body sweeps the fields of view across the target.

In one embodiment, the optical cells are arranged in a column parallel to the axis with a predefined pitch between the optical cells, and the planar reflective facets are configured to scan each of the fields of view along different respective rows across the target.

There is additionally provided, in accordance with an embodiment of the invention, optical sensing apparatus, including a sensing module, which includes at least one photonic integrated circuit (PIC), including an array of optical sensing cells including respective edge couplers, which have respective optical axes parallel to a plane of the PIC and define respective optical apertures of the optical sensing cells. At least one turning mirror is disposed in proximity to the edge couplers and configured to deflect the optical axes to a direction perpendicular to the plane of the PIC. Optics have a rear plane in proximity to the at least one PIC, and are configured to image the optical apertures onto a target, wherein the sensing module is configured such that a first optical path length between an edge coupler in a central part of the array and the rear plane of the optics is greater than a second optical path length between the edge couplers in a peripheral part of the array and the rear plane of the optics.

In one embodiment, an edge of the PIC in proximity to the at least one turning mirror has a concave shape, and the edge couplers are disposed along the edge.

Additionally or alternatively, the PIC contains grooves extending inward from an edge of the PIC that is in proximity to the at least one turning mirror along the respective optical axes of the edge couplers, such that the grooves in the central part of the array are longer than the grooves in the peripheral part of the array, and wherein the edge couplers are disposed at respective inner ends of the grooves.

Further additionally or alternatively, the at least one PIC includes multiple PICs mounted side by side on a carrier substrate, each PIC containing a respective group of the optical sensing cells and the respective edge couplers, wherein one or more of the PICs in the central part of the array are mounted at a greater distance from the at least one turning mirror than the PICs in the peripheral part of the array.

Still further additionally or alternatively, the at least one turning mirror includes multiple turning mirrors mounted side by side on a carrier substrate, wherein one or more of the turning mirrors that are positioned to deflect the optical axes of the edge couplers in the central part of the array are mounted at a greater distance from the edge couplers than the turning mirrors that are positioned to deflect the optical axes of the edge couplers in the peripheral part of the array.

In a disclosed embodiment, the at least one PIC includes multiple PICs mounted side by side, each PIC containing a respective group of the optical sensing cells and the respective edge couplers, and the at least one turning mirror includes multiple turning mirrors mounted side by side, and the PICs and the turning mirrors in the peripheral part of the array are elevated relative to one or more of the PICs and one or more of the turning mirrors in the central part of the array.

There is further provided, in accordance with an embodiment of the invention, a method for producing an optoelectronic device. The method includes providing a photonic integrated circuit (PIC), including a PIC substrate, optical waveguides disposed on the PIC substrate, and electrical conductors disposed on the PIC substrate and connecting to one or more first electrical connection pads on the PIC substrate. A first side of the PIC substrate is mounted on a carrier substrate. At least one electronic integrated circuit is mounted on a second side of the PIC substrate, opposite the first side, the at least one electronic integrated circuit including a semiconductor substrate having one or more electronic circuit components thereon connected electrically to second electrical connection pads disposed on the semiconductor substrate. The second electrical connection pads are connected to the first electrical connection pads on the PIC substrate.

There is moreover provided, in accordance with an embodiment of the invention, a method for scanning, which includes mounting a mirror body to rotate about an axis, and disposing a plurality of planar reflective facets on the mirror body at different, respective azimuthal angles about the axis and tilted relative to the axis at different, respective inclination angles.

There is furthermore provided, in accordance with an embodiment of the invention, a method for optical sensing, which includes providing a sensing module, including at least one photonic integrated circuit (PIC), including an array of optical sensing cells including respective edge couplers, which have respective optical axes parallel to a plane of the PIC and define respective optical apertures of the optical sensing cells, and at least one turning mirror disposed in proximity to the edge couplers so as to deflect the optical axes to a direction perpendicular to the plane of the PIC. The optical apertures are imaged onto a target using optics, which have a rear plane in proximity to the at least one PIC. The sensing module is configured such that a first optical path length between an edge coupler in a central part of the array and the rear plane of the optics is greater than a second optical path length between the edge couplers in a peripheral part of the array and the rear plane of the optics.

The present invention will be more fully understood from the following detailed description of the embodiments thereof, taken together with the drawings in which:

### BRIEF DESCRIPTION OF THE DRAWINGS

FIG. 1 is a schematic pictorial illustration of a transceiver array device, in accordance with an embodiment of the invention;

FIG. 2 is a block diagram that schematically shows details of the transceiver array device of FIG. 1, in accordance with an embodiment of the invention;

FIG. 3 is a schematic pictorial illustration of a transceiver array device, in accordance with another embodiment of the invention;

FIG. 4 is a schematic sectional view of the transceiver array device of FIG. 3;

FIG. 5 is a schematic pictorial illustration of a transceiver array device, in accordance with yet another embodiment of the invention;

FIG. 6 is a schematic sectional view of the transceiver array device of FIG. 5;

FIG. 7 is a schematic pictorial illustration of a scanning optical sensing device with a rotating polyhedral mirror, in accordance with an embodiment of the invention;

FIG. 8 is a schematic sectional view of the optical sensing device of FIG. 7;

FIGS. 9A, 9B, 9C, 9D, 9E, 9F and 9G are schematic frontal views of a scan pattern generated on a target by an optical sensing device, in accordance with an embodiment of the invention;

FIG. 10A is a schematic sectional view of a transceiver array device with a sensing module that accommodates optical field curvature, in accordance with an embodiment of the invention;

FIG. 10B is a schematic pictorial view of a sensing module that accommodates optical field curvature, in accordance with an embodiment of the invention;

FIG. 10C is a schematic frontal view of the sensing module of FIG. 10B;

FIG. 11A is a schematic pictorial view of a sensing module that accommodates optical field curvature, in accordance with another embodiment of the invention;

FIG. 11B is a schematic frontal view of the sensing module of FIG. 11A;

FIG. 12 is a schematic frontal view of a sensing module that accommodates optical field curvature, in accordance with yet another embodiment of the invention;

FIG. 13 is a schematic frontal view of a sensing module that accommodates optical field curvature, in accordance with a further embodiment of the invention;

FIG. 14A is a schematic sectional view of a transceiver array device with a sensing module that accommodates optical field curvature, in accordance with an alternative embodiment of the invention;

FIG. 14B is a schematic pictorial view of the sensing module of FIG. 14A; and

FIG. 14C is a schematic frontal view of the sensing module of FIG. 14B.

### DETAILED DESCRIPTION OF EMBODIMENTS

### Overview

As noted earlier, in coherent sensing applications, such as OCT and CW LiDAR, a coherent beam is transmitted toward a target, and the reflected radiation is sensed and processed coherently with the transmitted radiation. To sense the properties of the target with high resolution, the area of interest should be probed densely. Arrays of optoelectronic transmitters and receivers are useful for this purpose, but their resolution is limited by the pitches of the arrays, which are, in turn, limited by the sizes of the transmitters and receivers themselves. In many applications, electronic circuits are integrated closely with the optoelectronic devices for driving the transmitters and processing signals output by the receivers. These circuits tend to increase the pitch and overall size of the sensing device even further

PCT Patent Application PCT/US2022/40526 and PCT Patent Application PCT/US2022/40527, both filed Aug. 17, 2022, whose disclosures are incorporated herein by reference, describe solutions in which the sensing resolution of an array is enhanced by scanning the fields of view of the sensing cells in the array. Such scanning can be accomplished, for example, by optomechanical means such as a rotating mirror or translation of the scanning optics or the array. The embodiments described in these PCT patent applications use transceiver array chips based on photonic integrated circuit (PIC) technology. Each chip includes optical components for transmitting and sensing a beam of radiation, along with ancillary electronics.

In some of the embodiments described in these PCT patent applications, the beams that are to be transmitted are generated centrally, by a core transceiver engine, and the beams are then multiplexed among the individual transceivers, also referred to herein as transceiver cells. This arrangement is useful in reducing the size and power requirements of the transceiver chips. A scanner, such as an optomechanical scanning device, scans the beams of all the transceiver cells over the area of interest so that the area is covered densely—with resolution finer than the pitch of the array—and with high throughput. The multiplexing and scanning may be controlled so as to tailor the scan area and resolution to application requirements. The above-mentioned PCT patent applications describe a variety of array geometries and scan patterns that can be used for these purposes.

The PIC-based transceiver array chips can be designed to meet application requirements, such as the sensing mode (for example, coherent or non-coherent, as well as sensitivity), the mode of input/output coupling (for example, vertically or through the edge of the chip, via a grating or via a mirror), and wavelength characteristics (spectral range, and single- or multiple-wavelength sensing).

The embodiments that are described hereinbelow expand on the concepts and implementations set forth in the above-mentioned PCT patent applications. The present embodiments are directed to improving the optical quality and density of scan coverage, as well as enabling efficient production and assembly of compact, low-cost transceiver array devices. Although the disclosed embodiments are directed to optical sensing, in the visible, infrared, or ultraviolet range, the principles of the present invention may alternatively be applied, mutatis mutandis, in other spectral ranges, such as microwave and millimeter wave radiation.

### Multi-Chip Devices

PIC technology is not yet capable of achieving the high density and high yield of electronic integrated circuits (EICs), such as complementary metal-oxide semiconductor (CMOS) chips. Therefore, for practical reasons, it can be advantageous to use several PICs, arranged together on a common carrier substrate, in creating a full transceiver array. It can also be useful to separate the functions of electronic control, logic, and signal processing onto one or more EICs, which are closely coupled to the PIC on which the transceiver array itself is formed.

The embodiments described below address these needs. Specifically, in some embodiments, an EIC is mounted on a PIC, which is in turn mounted on a carrier substrate. The electrical connection pads on the EIC are bonded or otherwise connected to corresponding electrical connection pads on the PIC. (In the context of the present description and in the claims, the term “pad” refers generally to any sort of structure on the surface of an integrated circuit that is used to make electrical contact with another device or substrate. Thus, in the present context, “pads” include, without limitation, not only flat conductive areas, but also structures such as bumps and pillars.) In this manner, the electronic circuit components in the EIC are coupled closely to the optoelectronic components in the PIC, such as optical transmitters and receivers (i.e., optical sensors). Mounting the EICs on the PICs is advantageous in producing compact devices, as well as maintaining close electrical coupling for transmission and processing of high-speed signals. Alternatively, under certain circumstances, it may be advantageous to co-manufacture some of the electronic components on the PIC.

Placing the PIC on the carrier substrate can simplify and improve the precision of optical alignment between the PIC and external optical components, such as turning mirrors, lenses, and optical fibers. The EIC can be connected to conductive traces on the carrier substrate either directly, for example by wire bonding, or through the PIC. In this latter mode of connection, the EIC may be connected to the traces on the carrier substrate by conductive vias passing through the PIC, for example, or by wire bonding between the PIC and these traces. The EIC and PIC may be connected face to face, as illustrated in the figures that follow, or by other types of connections.

Additionally or alternatively, in some embodiments, multiple EICs are mounted on a single PIC. In such embodiments, the PIC may serve as an interposer between the EICs, which communicate with one another through electrical conductors on the PIC. Another benefit of using a large PIC with two or more smaller EICs mounted on the PIC (as opposed to a large EIC with several smaller PICS) is in reducing the need for precise alignment between PICs. Such precise alignment is typically required for optical interfaces between PICs or when several PICs create a single optical interface to free space optics. By contrast, electrical interfaces require only coarser alignment between bumps and pads.

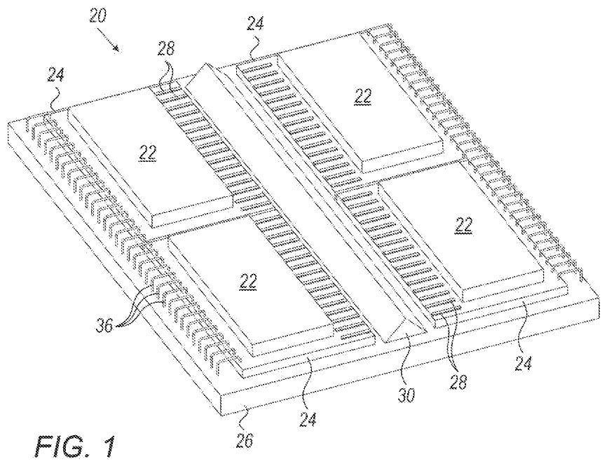

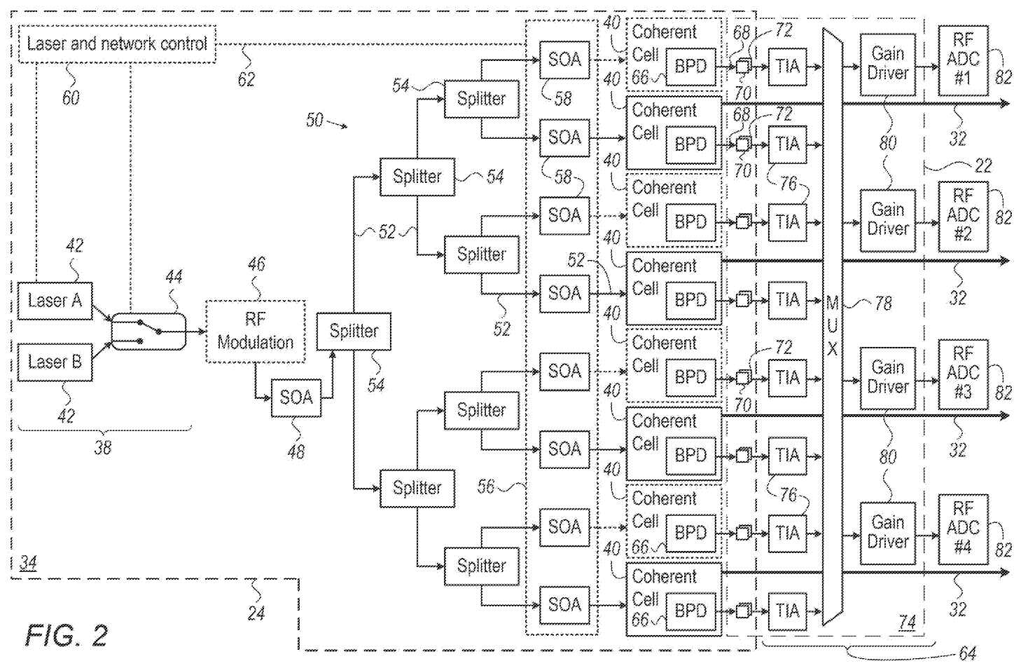

Reference is now made to FIGS. 1 and 2, which schematically illustrate a transceiver array device 20 in which EICs 22 are mounted on PICs 24, which are in turn mounted on a carrier substrate 26, in accordance with an embodiment of the invention. FIG. 1 is a pictorial illustration of device 20, while FIG. 2 is a block diagram showing details of one PIC 24 and the corresponding EIC 22. Each PIC 24 generates an array of optical beams 32, which are emitted through edge couplers 28 along the edge of the PIC toward a central turning mirror 30, which deflects the beams toward a target. Each PIC 24 also receives returning radiation that is reflected from the target via the turning mirror back to the edge of the PIC.

PIC 24 comprises a PIC substrate 34, whose lower side is mounted on carrier substrate 26. For example, PIC substrate 34 may comprise a silicon-on-insulator (SOI) die or another suitable type of semiconductor or dielectric wafer, while carrier substrate 26 comprises silicon, ceramic, or other suitable type of material. In the embodiment shown in FIG. 1, PICs 24 are connected electrically to connecting pads on carrier substrate 26 by wire bonds 36. Alternatively or additionally, the electrical connections between PICs 24 and carrier substrate 26 may be made via connecting pads on the lower surface of PICs 24 (as shown in FIG. 4, for example).

Each PIC 24 comprises optoelectronic components, including an optical transmitter 38 and an array of sensors, which comprise optical transceiver cells 40 in the present embodiment. Transmitter 38 in this example comprises a pair of lasers 42, which output beams of coherent radiation, with an optical switch 44 to select one of the lasers. The pair of lasers 42 is useful in providing redundancy, in case one of the lasers malfunctions, as well as for reducing the effects of laser speckle. In one embodiment, the two lasers 42 have different wavelengths, which can be useful multi-spectral sensing of the target, as well as improving the robustness of device 20 against strong ambient radiation or strong absorption at one of the wavelengths. Optical switch 44 is typically configured as a 2:1 multiplexer, and lasers 42 can be turned on one at a time. Optical switch 44 can be implemented, for example, as a 2×2 Mach Zehnder interferometer, with active control that directs both laser inputs to a single output. Alternatively, optical switch 44 (possibly configured as a Mach Zehnder interferometer) may have two outputs and map each of the laser beams to a different output, feeding a different, respective group of transceiver cells 40. As another option, when lasers 42 operate at different wavelengths, optical switch 44 may comprise a wavelength-division multiplexer.

In the pictured embodiment, the selected beam is modulated by an RF modulator 46 and, optionally, amplified by a semiconductor optical amplifier (SOA) 48. Alternatively, the lasers may be directly modulated. In either case, the selected beam is distributed by a hierarchical optical network 50 to transceiver cells 40. Optical network 50 comprises optical waveguides 52 connected to optical splitters 54, which split the input beam from transmitter 38 into eight separate beams. Although transmitter 38 and transceiver cells 40 are contained all together in a single PIC 24 in the present example, in alternative embodiments the transmitter and transceiver cells may be formed on separate PICs, which are connected optically by optical fibers or edge couplers, for example.

An optical multiplexer 56 on PIC 24, comprising an array of SOAs 58, multiplexes the beams from optical network 50 among transceiver cells 40. Each beam is input to a corresponding SOA 58, which is switched on or off by a drive circuit 60 via an electrical control bus 62. Drive circuit 60 thus controls the operation of optical network 50 so as to multiplex output beams 32 among transceiver cells 40: By switching SOAs 58 on or off, drive circuit 60 is able to select a subset of one or more of the beams 32 to transmit from the PIC. Typically, the setting of multiplexer 56 can be changed in the course of scanning a given target, to scan different areas of the target or to increase or decrease the density of the scan. In the example shown in FIG. 1, drive circuit 60 is formed together with analog signal processing circuits 64 (commonly referred to as analog front end [AFE] circuits) on the same EIC 22. Radio frequency analog/digital converters (RF ADCs) 82 convert the signals to digital form, for input to digital signal processing circuits (not shown in this figure). Alternatively, drive circuit 60 and signal processing circuits 64 may be formed on separate EICs.

Each beam from multiplexer 56 is input to a corresponding transceiver cell 40, which transmits the outgoing (Tx) beam 32 toward a target and receives and detects incoming (Rx) radiation that has been reflected from the target. Various cells of this sort are described in the above-mentioned PCT patent applications. In the present example, transceiver cells 40 are assumed to be coherent sensing cells, which mix a part of the outgoing beam that they have received via waveguides 52 with incoming optical radiation that is reflected from the target and is incident on the transceiver cell. An optoelectronic component, such as a balanced photodiode (BPD) 66, outputs electrical signals in response to the mixed optical radiation.

BPDs 66 are connected by respective electrical conductors 68 on PIC substrate 34 to electrical connection pads 70 on the upper side of the PIC substrate (i.e., the side opposite carrier substrate 26). Connection pads 70 are connected to corresponding connection pads 72 on a semiconductor substrate 74 of EIC 22. When EIC 22 is mounted such that connection pads 72 are disposed on the side facing away from PIC 24 (i.e., on the upper side in the view shown in FIG. 1), the connections may be made, for example, by wire bonding. Alternatively, EIC 22 may be mounted on PIC 24 in a “flip-chip” configuration, with connection pads 72 facing downward, in alignment with and bonded to connection pads 70 (as shown in FIG. 6, for example).

EIC 22 comprises electronic circuit components disposed on semiconductor substrate 74 and connected electrically to electrical connection pads 72. Semiconductor substrate 74 typically comprises a silicon die, although other types of semiconductor substrates may alternatively be used. In the pictured example, the electrical signal output by each BPD 66 passes to a corresponding transimpedance amplifier (TIA) 76 in EIC 22 via a pair of connection pads 70 and 72. TIA 76 amplifies the signal. Since only a subset of beams 32 are switched on at any given instant (four beams in the present example), only the signals output by the BPDs in the corresponding transceiver cells 40 will contain useful information. A multiplexer (MUX) 78 in EIC 22 selects the signals to be processed on this basis, i.e., at any given time during a scan, MUX 78 selects the same transceiver cells 40 that are selected by multiplexer 56 to output beams 32. The signals selected by MUX 78 are input to signal processing circuits, including respective gain drivers 80 and radiofrequency analog/digital converters (RF ADCs) 82. This sort of combined optical and electronic multiplexing is useful in reducing the size and power consumption of the signal processing circuits in the EIC.

Although PIC 24 in the present embodiment comprises eight transceiver cells 40, in alternative embodiments a single PIC may contain a smaller or larger number of sensors, from a single sensor up to tens or even hundreds of sensors using technologies that are presently available. The sensors may comprise coherent transceiver cells, as in the present embodiment, or they may comprise sensing components of other sorts. Furthermore, although PIC 24 comprises edge couplers 28 for transmitting and receiving optical radiation from and to transceiver cells 40, the PIC may alternatively comprise optical transducers of other types, such as grating couplers. The pairs of electrical connection pads 70 and 72 may be used not only for outputting signals from sensors on the PIC to processing circuits on the EIC, but also for exchanging other sorts of electrical signals, including drive and control signals, as well as power and timing signals, for example. All such alternative implementations are considered to be within the scope of the present invention.

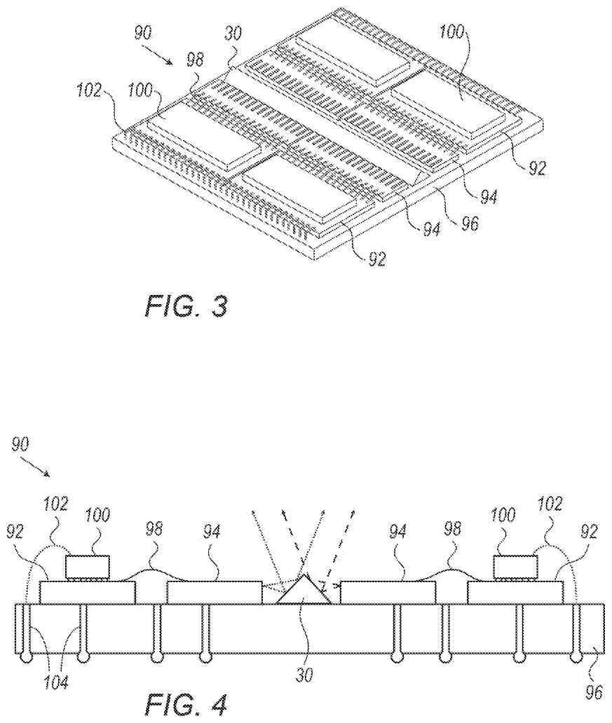

Reference is now made to FIGS. 3 and 4, which schematically illustrate a transceiver array device 90, in accordance with an alternative embodiment of the invention. FIG. 3 is a pictorial view, while FIG. 4 is a sectional view. In this embodiment, multiple PICs 92, 94 of two different types are mounted together on a carrier substrate 96 and share triangular turning mirror 30, with two pairs of PICs 92 and 94 on each side of the mirror. For example, PIC 92 may comprise an optical switching network, which generates an array of beams, while PIC 94 comprises an array of transceiver cells. The beams generated by each PIC 92 are conveyed by suitable waveguides 98, for example by optical wire bonds, or by other means, such as edge couplers, to the corresponding PIC 94.

Alternatively, the optical functions of the transceiver array device may be partitioned differently between the PICs. For example, PIC 92 can be an active chip containing lasers, modulators, SOAs, and possibly some components of the optical distribution and switching network, while PIC 94 contains some additional switching components, along with the transceiver cells. PICs 92 and 94 are typically coupled together both optically and electrically.

An EIC 100 is mounted on each PIC 92 and performs control and signal processing functions in connection with controlling the switching network in PIC 92 and processing the signals output by the transceiver cells in the corresponding PIC 94. Alternatively or additionally, an EIC may be mounted on PIC 94. Further alternatively or additionally, multiple EICs having different functionalities may be mounted on one of the PICs, for example on PIC 92.

As in the preceding embodiment, the functions of EIC 100 may include, for example:
Driving semiconductor optical amplifiers (SOAs) in the PICS;
Driving and modulating laser diodes in or connected to the PICS;
Controlling optical switching networks in the PICS;
Amplification and analog/digital conversion (ADC) of the signals output by optical detectors in the PICS;
Digital signal processing of the detector outputs.

In the example shown in FIGS. 3 and 4, each EIC 100 is connected to the corresponding PIC 92 by an array of solder bumps (as shown in greater detail in FIG. 6, for example) and is connected to electrical traces on carrier substrate 96 by electrical wire bonds 102. Alternatively, the EICs and corresponding PICs may be interconnected by other means that are known in the art, such as copper pillars or wire bonding.

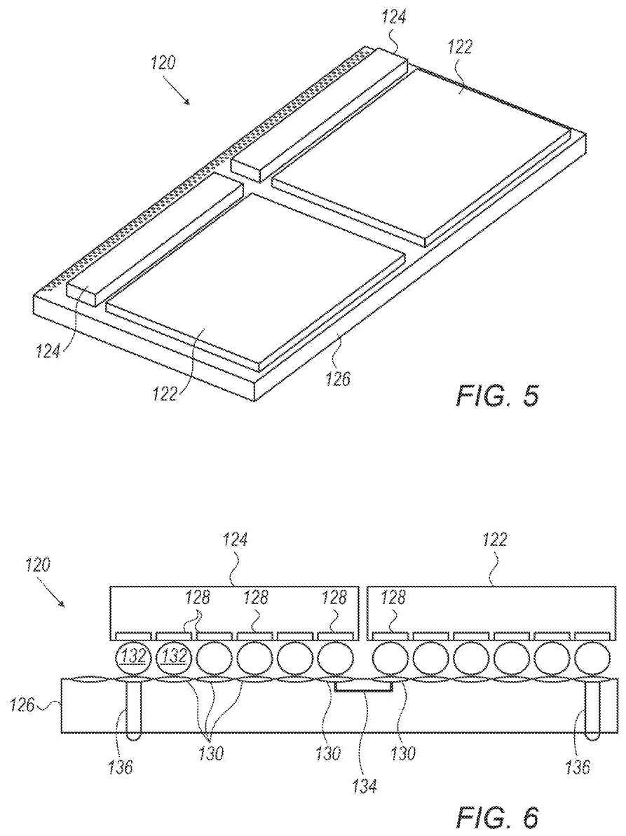

Reference is now made to FIGS. 5 and 6, which schematically illustrate a transceiver array device 120, in accordance with yet another embodiment of the invention. FIG. 5 is a pictorial view, while FIG. 6 is a sectional view. In this embodiment, multiple EICs 122, 124 are mounted together on the same PIC 126. For example, EIC 122 may comprise the transmitter driver, optical network switching control, and analog front end functions of the signal processing circuits, while EIC 124 performs digital processing functions.

EICs 122 and 124 are mounted on PIC 126 in a flip-chip configuration, with electrical connection pads 128 on the lower side of the EICs in alignment with and bonded to corresponding electrical connection pads 130 on PIC 126. Electrical connection pads 128 and 130 can be bonded together using solder bumps 132 or any other suitable bonding technology. Electrical connection pads 128 on EICs 122 and 124 may be connected together electrically as necessary by electrical conductors 134 running between corresponding electrical connection pads 130 on PIC 126. Additionally or alternatively, electrical circuit components on EICs 122 and 124 may be connected to conductive traces on the carrier substrate (for example, substrate 26 in FIG. 1) by conductive vias 136 running through PIC 126 and connecting to electrical connection pads 128 and 130 on EIC 122 and/or 124.

Polyhedral Scanner with Variable Facet Inclination

Many optical scanning applications call for deflection of a beam or of the field of view of a sensor in two dimensions, for example to scan the beam or field of view in a raster pattern comprising multiple parallel scan lines across a target. This sort of two-dimensional scanning is typically accomplished either using a gimballed mirror, which rotates about two axes, or by a pair of scanning elements, which are arranged in series to provide deflection in two perpendicular directions. For example, a rotating polygonal mirror may scan a beam at high speed along a first direction (typically perpendicular to the axis of rotation of the polygonal mirror), while the beam is scanned at lower speed in a second, perpendicular direction by a galvanometer mirror or by shifting an element of the projection optics.

Some embodiments of the present invention provide an alternative solution, in which two-dimensional scanning is achieved using a scanner comprising a single rotating polyhedral mirror. In these embodiments, the mirror comprises a body configured to rotate about an axis. Multiple planar reflective facets are disposed on the body at different, respective azimuthal angles about the axis. The reflective facets are tilted relative to the axis at different, respective inclination angles. Thus, as the scanner rotates, each of the reflective facets will scan an incident beam rapidly along a respective scan line perpendicular to the axis of rotation, while each facet will displace the scan line in a direction parallel to the axis by a different amount, depending on the respective inclination angle of the facet.

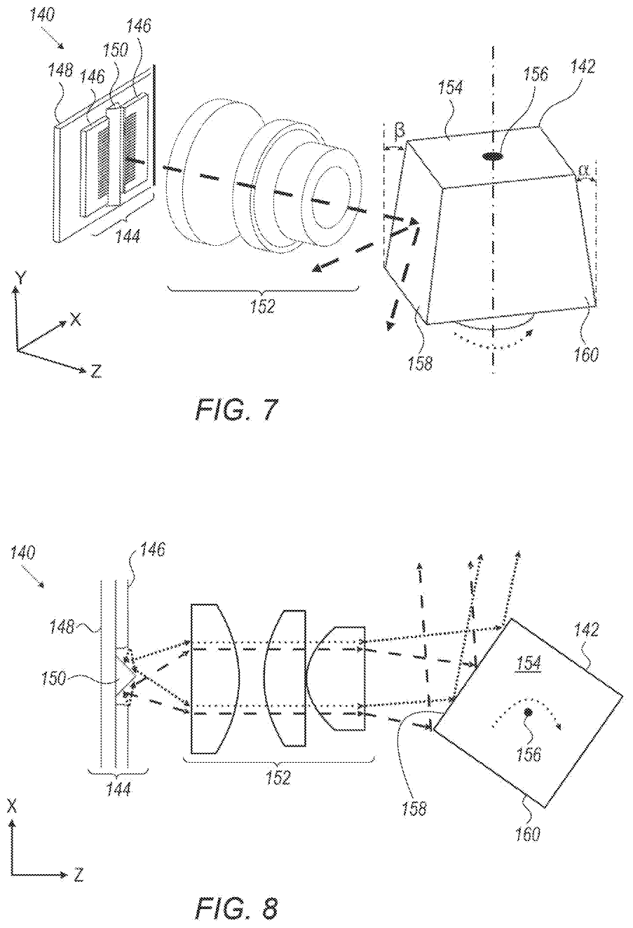

Reference is now made to FIGS. 7 and 8, which schematically illustrate a scanning optical sensing device 140 with a rotating polyhedral mirror 142, in accordance with an embodiment of the invention. FIG. 7 is a pictorial illustration, while FIG. 8 is a sectional view.

Polyhedral mirror 142 comprises a body 154 mounted to rotate about an axis 156, which is taken to be parallel to the Y-axis. Multiple planar reflective facets 158, 160, . . . are formed on or fixed to body 154 at different, respective azimuthal angles about axis 156. Each facet 158, 160, . . . , is tilted relative to axis 156 at a different, respective inclination angle. Thus, for example facet 160 is tilted at an angle α, while facet 158 is tilted at a different angle β.

Device 140 comprises a transceiver array 144, comprising a pair of edge-emitting PICS 146, mounted on a common carrier substrate 148. As in the embodiment of FIG. 1, each transceiver cell in array 144 comprises an edge coupler, which defines the optical aperture of the transceiver cell. PICs 144 emit respective sets of beams through the optical apertures of the transceiver cells toward a central triangular mirror 150, which turns the beams away from substrate 148, as illustrated by the dashed arrows in FIGS. 7 and 8. Transceiver array 144 may comprise the sorts of integrated PIC/EIC devices that are described above. Alternatively, device 140 may comprise any other suitable sort of transceiver array, such as the various sorts of arrays that are described in the above-mentioned PCT patent applications, including either edge-emitting or surface-emitting transceiver cells. Further alternatively, rotating polyhedral mirror 142 may be used in other applications in which transmitted beams and/or fields of view of sensing elements are to be scanned across a target region.

Optics 152 image the optical apertures of the transceiver cells in array 144 via reflective facets 158, 160 . . . , of polyhedral mirror 142 onto respective fields of view on a target. Optics 152 thus collimate the beams transmitted by the transceiver cells. As polyhedral mirror 142 turns about axis 156, the fields of view of the transceiver cells are swept across the target. Specifically, the beams emitted by transceiver array 144 are reflected from mirror 142 and are thus scanned across the target along the X-direction. Because each of facets 158, 160, . . . , is inclined at a different, respective angle, however, each facet deflects the beams at a different angle in the Y-direction as the beams reflect from the facet. Although mirror 142 is shown in FIGS. 7 and 8 as having four such reflective facets, in alternative embodiments the mirror may have a larger number of reflective facets, each with its own inclination angle, or possibly only three facets.

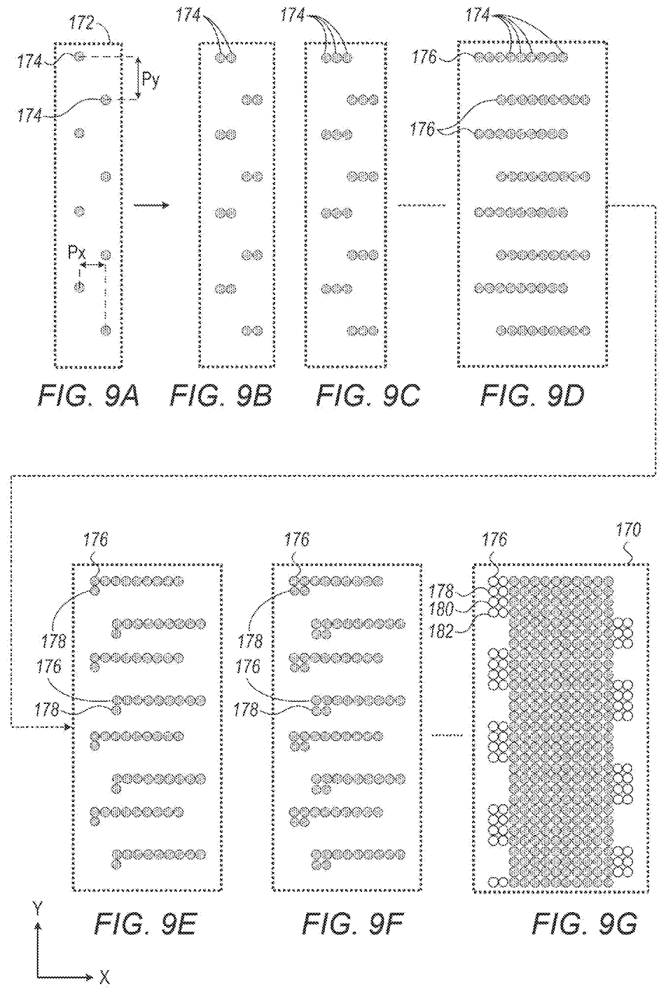

FIGS. 9A, 9B, 9C, 9D, 9E, 9F and 9G are schematic frontal views of a scan pattern 170 generated on a target by optical sensing device 140, in accordance with an embodiment of the invention. When polyhedral mirror 142 is stationary, transceiver array 144 generates a pattern 172, shown in FIG. 9A, comprising two parallel columns of beams 174 (or equivalently, two parallel columns of optical apertures) extending along the Y (vertical) direction. In this example, the PICS 146 on the opposing sides of central turning mirror 150 are offset along the Y direction by a small angular separation, for example a separation corresponding to half the vertical pitch of the arrays, thus creating staggered beam pattern 172, with a vertical pitch P_{Y}. The horizontal pitch P_{X} is determined by the width of turning mirror 150.

As a given facet (for example, facet 160) of polyhedral mirror 142 turns across the beam paths, each beam 174 will be scanned along a row 176 of locations across the X (horizontal) direction, as illustrated in FIGS. 9B-9D. As the next facet (for example, facet 158) turns across the beam paths, at a different inclination angle, each beam 174 will be scanned along another horizontal row 178 that is displaced vertically relative to the preceding row, as shown in FIGS. 9E-9F. Scanning across all the facets of polyhedral mirror 142 will generate a full scan pattern 170 comprising a dense matrix of spots distributed along rows 176, 178, 180 and 182, filling in the gaps in both P_{X} and P_{Y}, as shown in FIG. 9G.

Although this embodiment and the other embodiment described herein use edge-coupled PICs with turning mirrors, the principles of these embodiments can alternatively be applied using other coupling schemes, such as grating couplers, as well as other types of optical transducers.

### Improving Optical Quality Using Field Curvature

As shown in FIGS. 7 and 8 above, for example, the beams that are output from an optical transceiver array are typically collimated by a collimation lens before being scanned over the target. To scan and sense the target with high resolution, it is desirable that the beams be well collimated, with good control of aberrations and low divergence. One of the problems that the designer of a multi-beam scanning system must resolve in this regard is the field curvature that is inherent in any simple refractive lens. To achieve the desired optical quality in array scanning systems that are known in the art, it is often necessary to use a large, costly, multi-element collimation lens to reduce field curvature (as well as other aberrations).

Some embodiments of the present invention address this problem by providing sensing modules capable of accommodating substantial field curvature in the system optics. In these embodiments, the sensing module comprises at least one PIC comprising an array of optical sensing cells, for example the sorts of optical transceiver cells that were described above. The sensing cells comprise respective edge couplers, which have respective optical axes parallel to the plane of the PIC and define respective optical apertures of the optical sensing cells. At least one turning mirror, in proximity to the edge couplers, deflects the optical axes to a direction perpendicular to the plane of the PIC. Optics for imaging the optical apertures of the sensing cells onto a target are positioned with the rear plane of the optics in proximity to the PIC. In the context of the present description and in the claims, the “rear plane” of the optics is a plane that is perpendicular to the optical axis of the optics and passes through the optical surface of the optics that is closest to the PIC at the location on this optical surface that is closest to the PIC.

To accommodate the field curvature of the optics, the sensing module is configured such that the optical path length between the edge couplers in the central part of the array and the rear plane of the optics is greater than the optical path length between the edge couplers in the peripheral part of the array and the rear plane of the optics. In other words, the optical apertures of the sensing cells in the peripheral areas of the array are effectively closer to the rear plane of the optics that the sensing cells in the center. This adjustment of the optical path length can be accomplished, for example, by modifying the PIC, or the turning mirror, or both, as illustrated in the figures that follow.

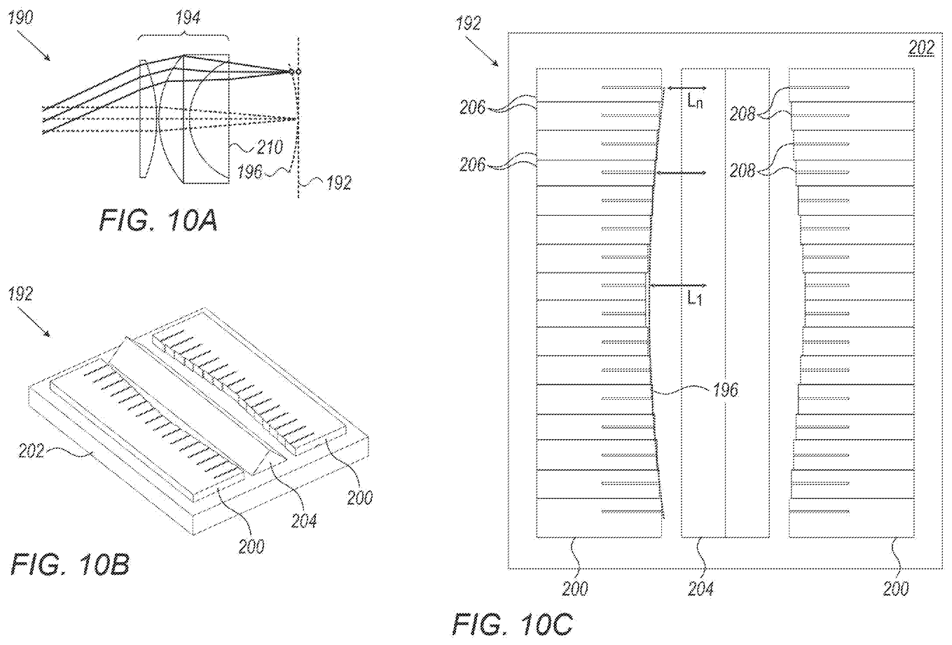

Reference is now made to FIGS. 10A, 10B and 10C, which schematically illustrate a transceiver array device 190 with a sensing module 192 that accommodates optical field curvature, in accordance with an embodiment of the invention. FIG. 10A is a schematic sectional view of device 190, while FIGS. 10B and 10C are pictorial and frontal views, respectively, of sensing module 192. Sensing module 192 comprises a pair of PICs 200 mounted on a carrier substrate 202 on opposing sides of a triangular turning mirror 204. Each PIC 200 comprises an array of transceiver cells 206, which terminate in respective edge couplers 208 in proximity to turning mirror 204. In FIG. 10A, sensing module 192 is represented simply as a plane, corresponding to the front surface of PICs 200.

As shown in FIG. 10A, device 190 comprises optics 194 having a curved field 196 in its rear focal plane, where sensing module 192 is located. If all the beams output by sensing module 192 were emitted from points along a plane, for example along the straight edge of a conventional PIC, the focal quality of the projected beams would vary because of the mismatch between the planar array output and the curved field of the lens.

To solve this problem, the edges of PICs 200 in proximity to mirror 204 are curved into a concave shape, for example by a process of deep reactive ion etching (DRIE). Reactive ion etching (RIE) may be applied to the upper layers of the PICs for improved etch quality. Alternatively, the edges of the PICs may be etched in a stair-step concave pattern that approximates a curve corresponding to curved field 196 of optics 194. As a consequence of the concave shape of the edges of PICs 200, the optical apertures of transceiver cells 206, i.e., edge couplers 208 defined by the output facets of the waveguides carrying the beams to the edge of the PIC, are located at different distances from mirror 204 (labeled L₁, . . . , Lₙ in FIG. 10C). The optical path length (based on Lₙ) from the edge couplers at the periphery of array 200 to a rear plane 210 of optics 194 is shorter than the optical path length (based on L₁) from the edge couplers in the center of array 200 to rear plane 210.

The curvature of the output surface of PICs 200 can be designed in this manner to match the field curvature of the rear focal plane of optics 194. Thus, all the beams transmitted toward the target will have relatively uniform focal quality, while enabling the optical designer to simplify and reduce the size and cost of optics 194.

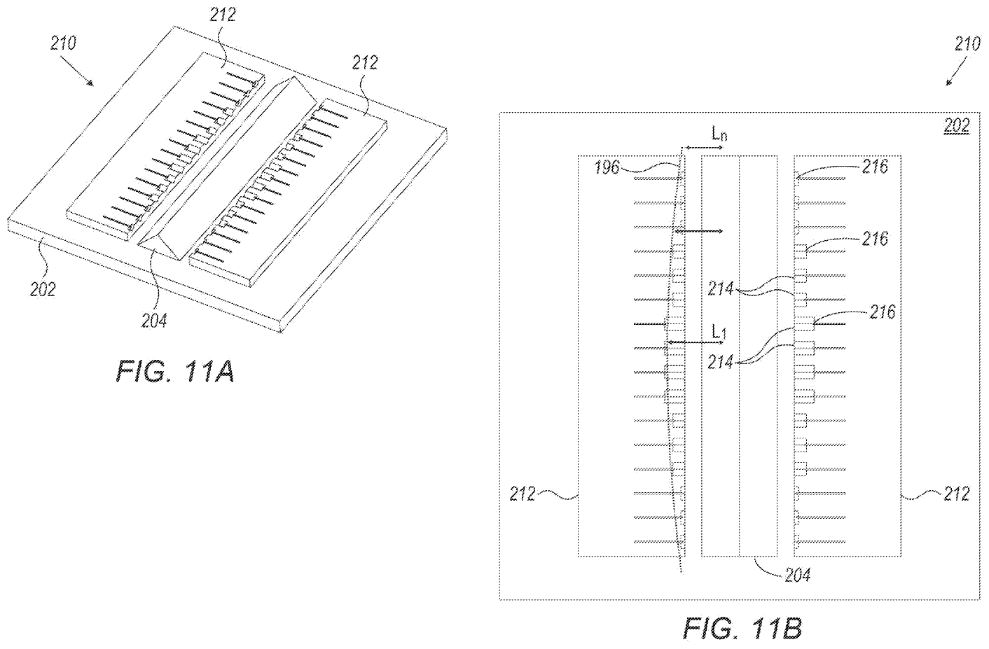

FIGS. 11A and 11B are schematic pictorial and frontal views, respectively, of a sensing module 210, which implements another approach to the problem of field curvature, in accordance with an embodiment of the invention. Sensing module 210 may be used in transceiver array device 190 in place of sensing module 192 (as may the other sensing modules that are described hereinbelow). Components in the present and subsequent embodiments that are similar to those in sensing module 192 are labeled with the same indicator numbers.

Sensing module 210 comprises a pair of PICs 212, which comprise respective arrays of transceiver cells and are mounted on opposing sides of turning mirror 204. In this embodiment, however, the edges of PICs 212 remain straight. To vary the distances from the optical apertures of the transceiver cells to the rear plane of the optics, V-grooves 214 of different lengths are etched in proximity to the edge of each PIC 212 along the paths of the respective waveguides of the transceiver cells. Each transceiver cell has an edge coupler 216, defining the optical aperture of the transceiver cell, at the inner end of the corresponding V-groove 214. Thus, to match curved field 196, grooves 214 are etched relatively deeply into the PIC in the central part of the array but less deeply (or not at all) in the peripheral parts.

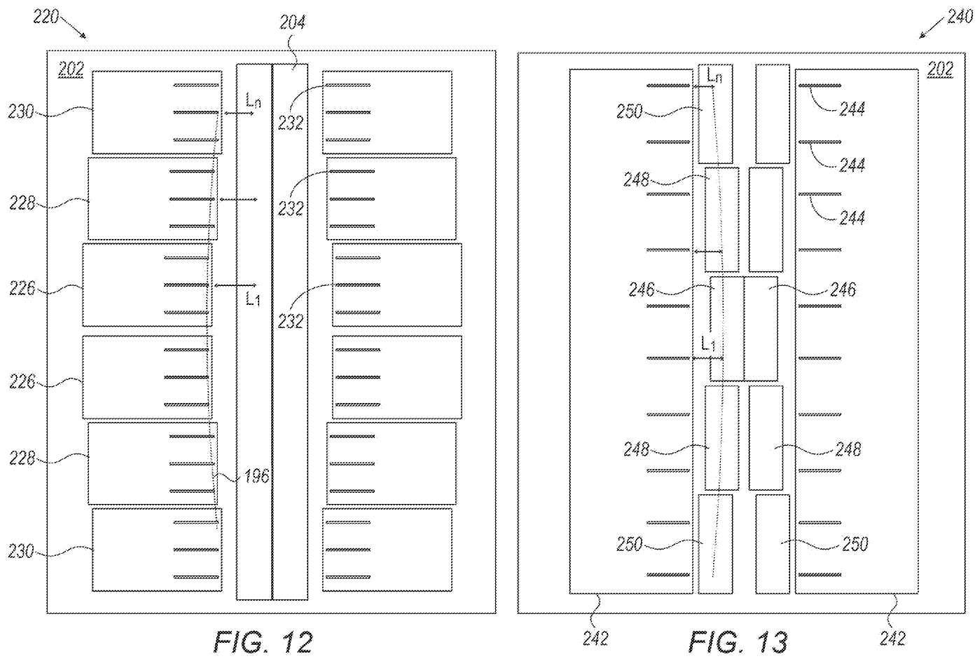

FIG. 12 is a schematic frontal view of a sensing module 220 that takes yet another approach to the problem of field curvature, in accordance with an embodiment of the invention. In this case, multiple PICs 226, 228, 230 are mounted side by side on carrier substrate 202 on opposing sides of turning mirror 294. Each PIC 226, 228, 230 contains a respective group of optical sensing cells with respective edge couplers 232. PICs 226 in the central part of the array are mounted at a greater distance from turning mirror 204 than PICs 230 in the peripheral part of the array. The positioning of PICs 226, 228, 230 on carrier substrate 202 can be chosen to approximate the field curvature of optics 194 (FIG. 10A).

FIG. 13 is a schematic frontal view of a sensing module 240 that takes an alternative approach to the problem of field curvature, in accordance with yet another embodiment of the invention. Sensing module 240 comprises a pair of PICs 242, having edge couplers 244 arrayed along straight edges of the PICs. Instead of a single turning mirror as in the preceding embodiments, multiple turning mirrors 246, 248, 250 are positioned on carrier substrate 202 at different distances from the edges of PICs 242. Specifically, turning mirrors 246, which deflect the optical axes of edge couplers 244 in the central part of the array, are mounted at a greater distance from the edge couplers than turning mirrors 250, which deflect the optical axes of edge couplers 244 in the peripheral part of the array. Consequently, the central part of the edge of each PIC 242 will effectively be farther from rear plane 210 of optics 194 than the outer parts, thus compensating approximately for the field curvature of the optics. In this embodiment, the beams and apertures will come out on the target along a curve, rather than a straight line as in the other embodiments; but the curvature will have only a small effect, which can be compensated in the scan pattern.

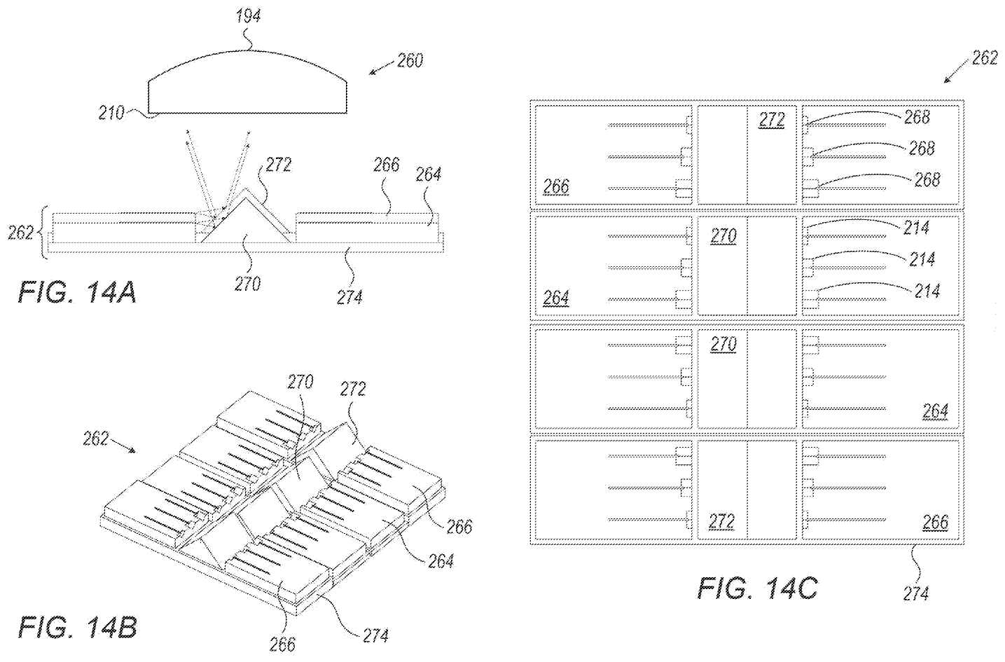

Reference is now made to FIGS. 14A, 14B and 14C, which schematically illustrate a transceiver array device 260 with a sensing module 262 that accommodates optical field curvature, in accordance with still another embodiment of the invention. FIG. 14A is a schematic sectional view of device 260, while FIGS. 14B and 14C are pictorial and frontal views, respectively, of sensing module 262.

In sensing module 262, multiple PICs 264, 266 are mounted side by side. Each PIC contains a respective group of the optical sensing cells, with respective edge couplers 268. Multiple turning mirrors 270, 272 are mounted side by side in proximity to the edge couplers of corresponding PICs 264, 266. PICs 266 and turning mirrors 272 in the peripheral part of the array in sensing module 262 are elevated relative to PICs 264 and corresponding turning mirrors 270 in the central part of the array. For example, carrier substrate 274, on which the PICS and mirrors are mounted, may be graduated, so that the peripheral part of the carrier substrate is higher than the central part, as shown in FIG. 14B.

In addition, as shown in FIG. 14C. V-grooves 214 of different lengths may be etched along the paths of the waveguides in proximity to the edge of each PIC 264, 266, so that edge couplers 268 are displaced by different distances from the edge of the PIC. The combination of the graduated heights and graduated groove lengths can provide a good approximation of the field curvature of the collimating lens.

Although each of the embodiments of FIGS. 10A-14C uses a particular feature or combination of features to create a curved output surface, other combinations of these features will be apparent to those skilled in the art after reading the present disclosure and are considered to be within the scope of the present invention. Furthermore, although for the sake of simplicity, these figures show sensing modules comprising small numbers of sensing cells, the principles of these embodiments may readily be extended to sensing modules that have larger or smaller numbers of sensing cells.

It will thus be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
a carrier substrate;
a photonic integrated circuit (PIC), comprising:
a PIC substrate, having a first side mounted on the carrier substrate;
first electrical connection pads disposed on a second side of the PIC substrate, opposite the first side;
optical waveguides disposed on the PIC substrate; and
electrical conductors disposed on the PIC substrate and connecting to one or more of the first electrical connection pads; and
at least one electronic integrated circuit, comprising:
a semiconductor substrate having a third side mounted on the second side of the PIC substrate;
second electrical connection pads disposed on the semiconductor substrate in electrical communication with the first electrical connection pads; and
one or more electronic circuit components disposed on the semiconductor substrate and connected electrically to the second electrical connection pads.

2. The device according to claim 1, and comprising one or more optoelectronic components disposed on the PIC substrate in optical communication with one or more of the optical waveguides and in electrical communication with one or more of the electrical conductors.

3. The device according to claim 2, wherein at least one of the optoelectronic components is configured to exchange electrical signals with at least one of the electronic circuit components via the first and second electrical connection pads.

4. The device according to claim 3, wherein the at least one of the optoelectronic components comprises an optical transmitter, and
wherein the at least one of the electronic circuit components comprises a drive circuit, which is coupled via the first and second electrical connection pads to control the optical transmitter.

5. The device according to claim 4, wherein the one or more optical components comprise an array of transceiver cells, and
wherein the optical transmitter comprises a radiation source configured to generate one or more output beams of optical radiation and an optical network coupled between the radiation source and the transceiver cells, and
wherein the drive circuit is configured to control the optical network so as to multiplex the one or more output beams among the transceiver cells.

6. The device according to claim 4, wherein the optical transmitter is configured to generate an output beam of coherent radiation, and
wherein the one or more optoelectronic components comprise at least one coherent sensor, which is configured to mix a part of the output beam with incoming optical radiation that is incident on the at least one coherent sensor and to output signals in response to the mixed optical radiation.

7. The device according to claim 3, wherein the at least one of the optoelectronic components comprises at least one sensor, which is configured to output signals in response to optical radiation that is incident on the at least one sensor, and
wherein the at least one of the electronic circuit components comprises one or more signal processing circuits, which are coupled via the first and second electrical connection pads to process the signals output by the at least one sensor.

8. The device according to claim 7, wherein the at least one sensor comprises an array of optical sensors, and
wherein the one or more electronic circuit components comprise a multiplexing circuit, which is configured to couple the optical sensors selectively to the one or more signal processing circuits.

9. The device according to claim 1, wherein the second electrical connection pads are disposed on the third side of the semiconductor substrate in alignment with and bonded to the first electrical connection pads.

10. The device according to claim 1, wherein the at least one electronic integrated circuit comprises first and second electronic integrated circuits, both mounted on the second side of the PIC substrate,
wherein the first electronic integrated circuit is in electrical communication with the second electronic integrated circuit via one of the electrical conductors connecting two of the first electrical connection pads on the PIC substrate.

11. The device according to claim 1, wherein the PIC comprises at least one conductive via, coupled between a conductive trace on the carrier substrate and at least one of the first electrical connection pads, which is in electrical communication with at least one of the second electrical connection pads, and
wherein at least one of the electronic circuit components is connected through the at least one of the first electrical connection pads, the at least one of the second electrical connection pads, and the at least one conductive via to the conductive trace on the carrier substrate.

12. An optical scanner, comprising:
a body configured to rotate about an axis; and
a plurality of planar reflective facets disposed on the body at different, respective azimuthal angles about the axis and tilted relative to the axis at different, respective inclination angles.

13. Optical apparatus, comprising:
the scanner according to claim 12;
an array of optical cells having respective optical apertures; and
optics configured to image the optical apertures via the reflective facets of the optical scanner onto respective fields of view on a target, whereby rotation of the body sweeps the fields of view across the target.

14. The apparatus according to claim 13, wherein the optical cells are arranged in a column parallel to the axis with a predefined pitch between the optical cells, and wherein the planar reflective facets are configured to scan each of the fields of view along different respective rows across the target.

15. Optical sensing apparatus, comprising:
a sensing module, comprising:
at least one photonic integrated circuit (PIC), comprising an array of optical sensing cells comprising respective edge couplers, which have respective optical axes parallel to a plane of the PIC and define respective optical apertures of the optical sensing cells; and
at least one turning mirror disposed in proximity to the edge couplers and configured to deflect the optical axes to a direction perpendicular to the plane of the PIC; and
optics, which have a rear plane in proximity to the at least one PIC, and which are configured to image the optical apertures onto a target,
wherein the sensing module is configured such that a first optical path length between an edge coupler in a central part of the array and the rear plane of the optics is greater than a second optical path length between the edge couplers in a peripheral part of the array and the rear plane of the optics.

16. The apparatus according to claim 15, wherein an edge of the PIC in proximity to the at least one turning mirror has a concave shape, and the edge couplers are disposed along the edge.

17. The apparatus according to claim 15, wherein the PIC contains grooves extending inward from an edge of the PIC that is in proximity to the at least one turning mirror along the respective optical axes of the edge couplers, such that the grooves in the central part of the array are longer than the grooves in the peripheral part of the array, and wherein the edge couplers are disposed at respective inner ends of the grooves.

18. The apparatus according to claim 15, wherein the at least one PIC comprises multiple PICS mounted side by side on a carrier substrate, each PIC containing a respective group of the optical sensing cells and the respective edge couplers, wherein one or more of the PICs in the central part of the array are mounted at a greater distance from the at least one turning mirror than the PICs in the peripheral part of the array.

19. The apparatus according to claim 15, wherein the at least one turning mirror comprises multiple turning mirrors mounted side by side on a carrier substrate,
wherein one or more of the turning mirrors that are positioned to deflect the optical axes of the edge couplers in the central part of the array are mounted at a greater distance from the edge couplers than the turning mirrors that are positioned to deflect the optical axes of the edge couplers in the peripheral part of the array.

20. The apparatus according to claim 15, wherein the at least one PIC comprises multiple PICs mounted side by side, each PIC containing a respective group of the optical sensing cells and the respective edge couplers, and wherein the at least one turning mirror comprises multiple turning mirrors mounted side by side, and
wherein the PICS and the turning mirrors in the peripheral part of the array are elevated relative to one or more of the PICS and one or more of the turning mirrors in the central part of the array.

21. A method for producing an optoelectronic device, the method comprising:
providing a photonic integrated circuit (PIC), comprising a PIC substrate, optical waveguides disposed on the PIC substrate, and electrical conductors disposed on the PIC substrate and connecting to one or more first electrical connection pads on the PIC substrate;
mounting a first side of the PIC substrate on a carrier substrate;
mounting at least one electronic integrated circuit on a second side of the PIC substrate, opposite the first side, the at least one electronic integrated circuit comprising a semiconductor substrate having one or more electronic circuit components thereon connected electrically to second electrical connection pads disposed on the semiconductor substrate; and
connecting the second electrical connection pads to the first electrical connection pads on the PIC substrate.

22. The method according to claim 21, wherein one or more optoelectronic components are disposed on the PIC substrate in optical communication with one or more of the optical waveguides and in electrical communication with one or more of the electrical conductors.

23. The method according to claim 22, wherein connecting the second electrical connection pads to the first electrical connection pads comprises coupling at least one of the optoelectronic components to exchange electrical signals with at least one of the electronic circuit components via the first and second electrical connection pads.

24. The method according to claim 23, wherein the at least one of the optoelectronic components comprises an optical transmitter, and
wherein the at least one of the electronic circuit components comprises a drive circuit, which is coupled via the first and second electrical connection pads to control the optical transmitter.

25. The method according to claim 24, wherein the one or more optical components comprise an array of transceiver cells, and
wherein the optical transmitter comprises a radiation source configured to generate one or more output beams of optical radiation and an optical network coupled between the radiation source and the transceiver cells, and
wherein coupling the at least one of the optoelectronic components comprises coupling the drive circuit to control the optical network so as to multiplex the one or more output beams among the transceiver cells.

26. The method according to claim 24, wherein the optical transmitter is configured to generate an output beam of coherent radiation, and
wherein the one or more optoelectronic components comprise at least one coherent sensor, which is configured to mix a part of the output beam with incoming optical radiation that is incident on the at least one coherent sensor and to output signals in response to the mixed optical radiation.

27. The method according to claim 23, wherein the at least one of the optoelectronic components comprises at least one sensor, which is configured to output signals in response to optical radiation that is incident on the at least one sensor, and
wherein coupling the at least one of the optoelectronic components comprises coupling one or more signal processing circuits via the first and second electrical connection pads to process the signals output by the at least one sensor.

28. The method according to claim 27, wherein the at least one sensor comprises an array of optical sensors, and
wherein coupling one or more signal processing circuits comprises multiplexing the one or more signal processing circuits among the optical sensors.

29. The method according to claim 21, wherein mounting the at least one electronic integrated circuit comprises mounting a third side of the semiconductor substrate on the second side of the PIC substrate, and
wherein the second electrical connection pads are disposed on the third side of the semiconductor substrate in alignment with and bonded to the first electrical connection pads.

30. The method according to claim 21, wherein mounting the at least one electronic integrated circuit comprises mounting first and second electronic integrated circuits on the second side of the PIC substrate, and
wherein connecting the second electrical connection pads comprises coupling the first electronic integrated circuit to communicate electrically with the second electronic integrated circuit via one of the electrical conductors connecting two of the first electrical connection pads on the PIC substrate.

31. The method according to claim 21, wherein the PIC comprises at least one conductive via coupled to at least one of the first electrical connection pads, and
wherein mounting the first side of the PIC substrate comprises coupling the at least one conductive via to a conductive trace on the carrier substrate, and
wherein connecting the second electrical connection pads comprises coupling at least one of the electronic circuit components to the conductive trace on the carrier substrate through at least one of the second electrical connection pads, the at least one of the first electrical connection pads, and the at least one conductive via.

32. A method for scanning, comprising:
mounting a mirror body to rotate about an axis; and disposing a plurality of planar reflective facets on the mirror body at different, respective azimuthal angles about the axis and tilted relative to the axis at different, respective inclination angles.

33. The method according to claim 32, and comprising:
providing an array of optical cells having respective optical apertures; and
imaging the optical apertures via the reflective facets of the optical scanner onto respective fields of view on a target, whereby rotation of the mirror body sweeps the fields of view across the target.

34. The method according to claim 33, wherein the optical cells are arranged in a column parallel to the axis with a predefined pitch between the optical cells, and wherein imaging the optical apertures comprises scanning each of the fields of view along different respective rows across the target as the reflective facets rotate about the axis.

35. A method for optical sensing, comprising:
providing a sensing module, comprising at least one photonic integrated circuit (PIC), comprising an array of optical sensing cells comprising respective edge couplers, which have respective optical axes parallel to a plane of the PIC and define respective optical apertures of the optical sensing cells, and at least one turning mirror disposed in proximity to the edge couplers so as to deflect the optical axes to a direction perpendicular to the plane of the PIC;
imaging the optical apertures onto a target using optics, which have a rear plane in proximity to the at least one PIC; and
configuring the sensing module such that a first optical path length between an edge coupler in a central part of the array and the rear plane of the optics is greater than a second optical path length between the edge couplers in a peripheral part of the array and the rear plane of the optics.

36. The method according to claim 35, wherein an edge of the PIC in proximity to the at least one turning mirror has a concave shape, and the edge couplers are disposed along the edge.

37. The method according to claim 35, wherein the PIC contains grooves extending inward from an edge of the PIC that is in proximity to the at least one turning mirror along the respective optical axes of the edge couplers, such that the grooves in the central part of the array are longer than the grooves in the peripheral part of the array, and wherein the edge couplers are disposed at respective inner ends of the grooves.

38. The method according to claim 35, wherein the at least one PIC comprises multiple PICs mounted side by side on a carrier substrate, each PIC containing a respective group of the optical sensing cells and the respective edge couplers, and
wherein configuring the sensing module comprises mounting one or more of the PICs in the central part of the array at a greater distance from the at least one turning mirror than the PICs in the peripheral part of the array.

39. The method according to claim 35, wherein the at least one turning mirror comprises multiple turning mirrors mounted side by side on a carrier substrate, and
wherein configuring the sensing module comprises mounting one or more of the turning mirrors that are positioned to deflect the optical axes of the edge couplers in the central part of the array at a greater distance from the edge couplers than the turning mirrors that are positioned to deflect the optical axes of the edge couplers in the peripheral part of the array.

40. The method according to claim 35, wherein the at least one PIC comprises multiple PICs mounted side by side, each PIC containing a respective group of the optical sensing cells and the respective edge couplers, and wherein the at least one turning mirror comprises multiple turning mirrors mounted side by side, and
wherein configuring the sensing module comprises elevating the PICS and the turning mirrors in the peripheral part of the array relative to one or more of the PICs and one or more of the turning mirrors in the central part of the array.
